(19) United States
(12) Patent Application Publication
(10) Pub. No.: US 2014/0370665 A1
(43) Pub. Date: Dec. 18, 2014

(54) POWER SEMICONDUCTOR DEVICE AND METHOD FOR MANUFACTURING SUCH A POWER SEMICONDUCTOR DEVICE

(71) Applicant: ABB Technology AG, Zurich (CH)

(72) Inventors: Munaf RAHIMO, Uezwil (CH); Chiara Corvasce, Bergdietikon (CH); Jan Vobecky, Lenzburg (CH); Yoichi Otani, Meisterschwanden (CH)

(73) Assignee: ABB Technology AG, Zurich (CH)

(21) Appl. No.: 14/477,229

(22) Filed: Sep. 4, 2014

Related U.S. Application Data
(63) Continuation of application No. PCT/EP2013/054169, filed on Mar. 1, 2013.

(30) Foreign Application Priority Data
Mar. 5, 2012 (EP) 12158043.5

(51) Int. Cl. H01L 29/66; H01L 21/283; H01L 21/324; H01L 21/225

(52) U.S. Cl. CPC H01L 29/66325; H01L 21/2251; H01L 21/283; H01L 21/324; H01L 29/6609
USPC 438/135; 438/542

(57) ABSTRACT

A method for manufacturing a power semiconductor device is disclosed which can include: providing a wafer of a first conductivity type; and applying on a second main side of the wafer at least one of a dopant of the first conductivity type for forming a layer of the first conductivity type and a dopant of a second conductivity type for forming a layer of the second conductivity type. A Titanium layer with a metal having a melting point above 1300° C. is then deposited on the second main side. The Titanium deposition layer is annealed so that simultaneously an intermetal compound layer is formed at the interface between the Titanium deposition layer and the wafer and the dopant is diffused into the wafer. A first metal electrode layer is created on the second main side.

### RELATED APPLICATION(S)

This application claims priority as a continuation application under 35 U.S.C. §120 to PCT/EP2013/054169, which was filed as an International Application on Mar. 1, 2013, designating the U.S., and which claims priority to European Application 12158043.5 filed in Europe on Mar. 5, 2012. The entire contents of these applications are hereby incorporated by reference in their entireties.

### FIELD

The present disclosure relates to the field of power electronics and, for example, to a method for manufacturing a power semiconductor device and a power semiconductor device as such.

### BACKGROUND INFORMATION

Known punch-through insulated gate bipolar transistors (IGBTs) can have a four-layer structure which includes a collector electrode on a collector side and an emitter electrode on an emitter side, which lies opposite the collector side. An (n−) doped drift layer is located between the emitter electrode and collector electrode. On the emitter side, a p doped base layer is arranged, which surrounds an n doped source region. These source region and base layer are in electrical contact with the emitter electrode. A gate electrode is also arranged on the emitter side (either planar gate or trench gate), which is electrically insulated from all other layers by an insulation layer.

An n doped buffer layer lies on the collector side between the base layer and the collector electrode. In the buffer layer, an electric field is stopped during operation of the device. On the buffer layer, towards the collector electrode, a p doped collector layer is arranged.

Such devices have been manufactured by epitaxial growth of the buffer layer.

Such devices have been further developed into non punch-through (NPT) devices, in which no buffer layer is present and the p collector layer lies directly adjacent to the (n−) doped drift layer. Such devices can offer advantages in terms of switching capability and current sharing of such chips which has enabled the employment of IGBTs into high current modules.

Such devices involve a thick wafer design to stop the electric field within the drift layer in the NPT concept. Therefore, such NPT devices have higher static and dynamic losses.

To address the electrical properties of IGBTs, soft-punch-through (SPT) devices have been introduced, which have thinner, but more highly doped buffer layers, thus resulting in thinner devices than the NPT devices, but without disadvantages of previous PT devices. Such devices can have improvements in terms of losses. Nevertheless, the SPT concepts involve complex processes when the wafer is thin, which is especially the case in low-voltage IGBTs for forming the backside layers including the collector and buffer layers.

Such a method is for example known from DE 198 29 614 A1. It describes a fabrication method for a soft punch-through insulated gate bipolar transistor (IGBT) 180 element (FIG. 1c)) based on a PT type which makes it possible to fabricate relatively thin semiconductor elements without having to employ the epitaxy method. For this purpose, a buffer layer 13 having a greater thickness than electrically is introduced into a lightly doped wafer, process steps for embodying the layers on the emitter sided surface (first main side 11) of the semiconductor element are then carried out (like base layer 5, source regions 6, gate electrode 7′ with its electrically conductive layer 75 and insulating layers 72, 74). Afterwards, the thickness of the buffer layer is reduced on the second main side 15 to the electrically specified size by grinding or polishing (dotted line in FIG. 1a). Thus, it is possible to carry out the emitter sided process steps on a relatively thick wafer, thereby reducing the risk of breaking. Nevertheless, by virtue of the subsequent thinning of the wafer, a semiconductor element having the desired small thickness can be produced. The minimum thickness of the finalized semiconductor elements is no longer limited by a minimum thickness that can be achieved for its starting material. Afterwards a p dopant is implanted and diffused for forming a collector layer 2 (FIG. 1b) and then a first electrode layer 4 is created on the second main side 15 (FIG. 1c)).

In U.S. Pat. No. 6,482,681 B1 another punch-through (PT) insulated gate bipolar transistor (IGBT) is described. The device is produced by using an (n−) doped wafer, on top of which all processes for manufacturing layers on the emitter side, also called cathode side are finished (i.e., all junctions and metallizations on the emitter side are produced). Afterwards, the wafer is thinned and hydrogen ions are implanted on the collector side of the wafer, also called anode side for forming an n+ doped buffer layer. Then a p dopant is implanted for forming a collector layer. The wafer is then annealed at 300 to 400 ° C. in order to activate the hydrogen ions without damage to the structure on the emitter side. Thus, the buffer layer serves, in the blocking case, for abruptly decelerating the electric field before the collector layer is reached and thus keeping the electric field away from the collector layer, since a semiconductor element can be destroyed if the electric field reaches the collector layer.

After thinning the device a p dopant is implanted for forming the p-type collector layer and activated by laser annealing followed by multi metal depositions and then a sinter process below 400° C. is made in a known furnace to activate the anode and form a good contact to the collector electrode. This process is limiting for achieving good control of the p-type anode collector activation. However, due to the restriction of the collector sided processes to temperatures below 400° C., the capability to control the anode (or cathode) activation levels and for forming good Si/metal contacts restricted. Device optimization for improved static and dynamic performance also involves a number of limiting process options.

By utilizing high energy laser annealing (e.g., above 1 J/cm2) after implantation, higher activation levels are possible. However, this impacts the Si wafer surface, but does not improve the metal contact because the metallization is made in a later step. The metallization processing and sintering is still a separate step.

Similar challenges are met when designing the fast recovery diodes based on thin wafer processing. In all these cases, the usage of an optimized laser annealing technology is inevitable for the creation of the p collector layer.

In US 2008/0076238 A1 a method for the creation of an IGBT is described, in which on a wafer Phosphorous ions are implanted and laser annealed for the creation of a buffer layer. Afterwards, boron ions are implanted and laser annealed for the creation of a collector layer. Then a Nickel film is applied on the collector layer and afterwards laser annealed. All laser anneal steps are performed separately.

EP 0 330 122 A1 describes an IGBT having an implanted p collector layer, which is annealed at a temperature below 600° C., on which a Platin layer is sputtered afterwards, which is then heated to 450 to 470° C. to form a Pt-Si compound layer. Afterwards, a multi-layered collector electrode is made of a titan layer, nickel layer and silver layer.

### SUMMARY

A method for manufacturing a power semiconductor device is disclosed, comprising: providing a wafer of a first conductivity type, which wafer has a first main side and a second main side opposite to the first main side, part of the wafer having unamended doping concentration forming a drift layer; applying on the second main side at least one of a dopant of the first conductivity type for forming a layer of the first conductivity type and a dopant of a second conductivity type, which is different from the first conductivity type, for forming a layer of the second conductivity type; depositing a Titanium deposition layer on the second main side after the applying of the dopant; laser annealing the Titanium deposition layer at a temperature higher than 1200° C. so that simultaneously an intermetal compound layer is formed at an interface between the Titanium deposition layer and the wafer and the at least one dopant is diffused into the wafer, and so that the Titanium deposition layer will act as a light absorber to achieve an increased temperature in the wafer below the Titanium deposition layer; and creating a first metal electrode layer on the second side.

### BRIEF DESCRIPTION OF DRAWINGS

The subject matter disclosed herein will be explained in more detail in the following text of exemplary embodiments as described with reference to the attached drawings, in which:

FIG. 1 shows an exemplary method for manufacturing a known power semiconductor device;

FIG. 2 shows an exemplary method as disclosed herein for manufacturing a power semiconductor device;

FIG. 3 shows an exemplary alternative for step a) of FIG. 2;

FIG. 4 shows an exemplary alternative for step b) of FIG. 2;

FIG. 5 an exemplary alternative for step d) of FIG. 2;

FIG. 6 another exemplary alternative for step d) of FIG. 2;

FIG. 7-9 shows different exemplary IGBTs as disclosed herein;

FIG. 10 shows an exemplary diode as disclosed herein; and

FIG. 11 is an exemplary a graphic which shows doping concentration versus depth in a wafer achieved with known methods and with an exemplary method as disclosed herein.

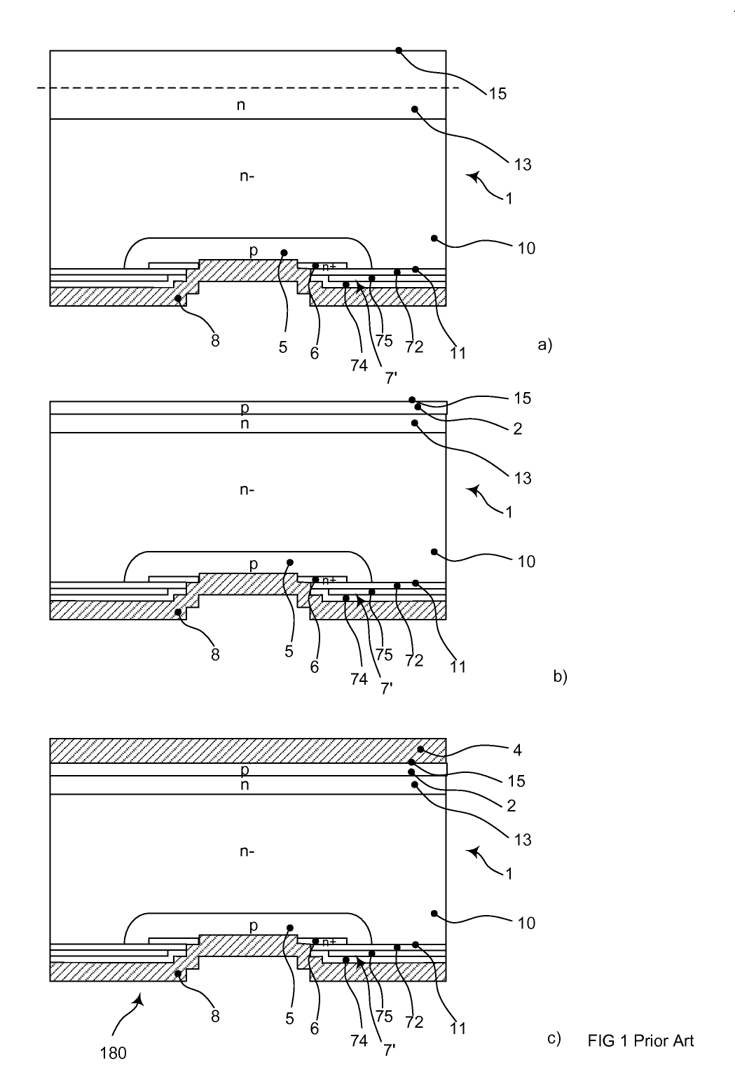

The reference symbols used in the figures and their meaning are summarized in the list of reference symbols. Generally, alike or alike-functioning parts are given the same reference symbols. The described embodiments are meant as examples and shall not limit the claimed invention.

### DETAILED DESCRIPTION

A method is disclosed for manufacturing a power semiconductor device, which can provide a better contact of the wafer to the electrode with an improved process capability and better device performance than known methods.

A exemplary method for manufacturing a power semiconductor device as disclosed herein can include:
providing a wafer of a first conductivity type, which wafer has a first main side and a second main side opposite to the first main side,
applying a dopant of a second conductivity type, which is different from the first conductivity type, or of the first conductivity type on the second main side, for forming a layer of the first or second conductivity type, respectively,
afterwards depositing a Titanium deposition layer, wherein Titanium has a melting point of 1660° C., (e.g., above that of silicon (1410° C.)) on the second main side,
annealing the Titanium deposition layer so that simultaneously an intermetal compound layer is formed at the interface between the Titanium deposition layer and the wafer and the dopant is diffused into the wafer, and
creating a first metal electrode layer on the second side.

Disclosed embodiments can for example be applied to thin wafers having a thickness of for example at most 200 μm as they are used for low voltage IGBTs (voltages of up to 2000 V) or for low voltage diodes (also up to 2000 V). The process capability can be improved by disclosed manufacturing methods and the device performance can also be improved compared to known SPT IGBTs and diodes.

By using methods disclosed herein, the activation of the collector dopant (like boron or Aluminum as a p dopant; or: Phoshorous or Arsenic as an n dopant) can be greatly improved which can be especially important when processing thin wafers and wafers of large diameters such as, for example, 200 mm or larger diameters.

The metal deposition layer made of Titanium can have a high temperature melting point since depending on the duration and energy of the laser pulse high temperatures can be produced on the wafer surface. Even short, but high energy laser pulses can produce temperatures higher than well above 1000° C. For example, laser pulses having an energy >1 J/cm² can be used. For example, a very short (for example, 200 ns) and high energy (e.g., 2 J/cm²) laser pulse can produce surface temperatures exceeding 1300° C. Therefore, Titanium having a melting point of 1660° C. and, thus higher than the temperature produced by the laser (e.g., higher than 1200° C. or even higher than 1300° C.) can be used. Titanium is applied as a thin layer after applying the dopant of the first or second conductivity type for forming a layer of the first or second conductivity type, and afterwards annealed. Titanium works in this step as a light absorber. The resulting effect is increased temperature in the wafer material (e.g., silicon) below the Titanium deposition layer, which leads to a higher activation of the dopant, because more energy is absorbed by the Titanium deposition layer for the same energy density of the laser beam. The thermal conductivity of the Titanium is small (21.9 W•m⁻¹.K⁻¹), so that there is not a big heat spread and more heat is utilized for underlying wafer material (e.g., silicon). The titanium silicide is created together with the activation of dopant. As it improves the contact resistance, it can be advantageous to keep the Titanium deposition layer as a part of the metal electrode layer.

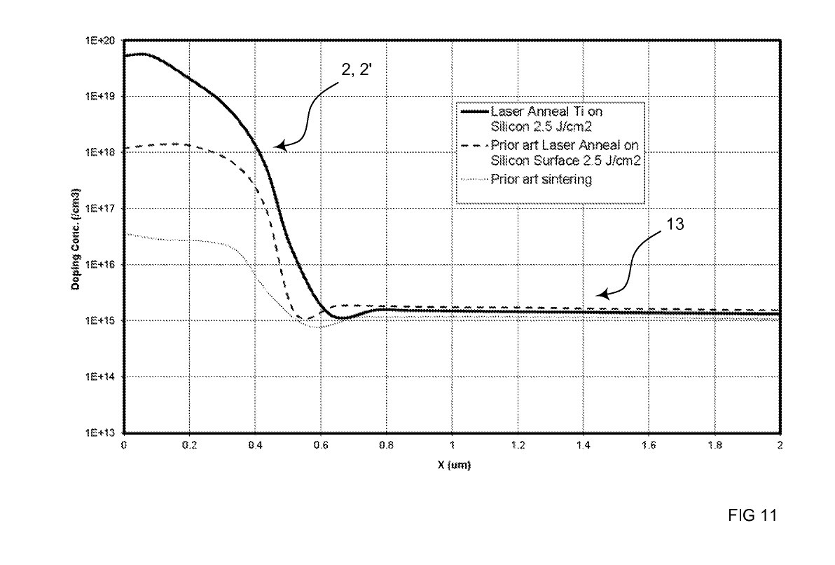

An exemplary advantage is that the Titanium deposition layer, having a melting point above 1600° C., absorbs the laser beam (heat) much more than the wafer surface. Therefore, a better activation of the dopants can be achieved and/or lower laser energies can be applied as shown in FIG. 11.

Titanium is capable of providing good contact Silicide layers with a Si wafer. These layers can also be used in addition to backside structures as desired for field charge extraction (FCE) concept diodes or reverse conducting IGBTs, which can include alternating p and n areas on the collector side.

In an exemplary method including a step of implantation of the dopant for forming a layer of the first or second conductivity type, the implantation step and the metal deposition step can be performed in two different tools. If depositing is used as a method to apply the dopant, the metal deposition layer can be created in the same apparatus.

The laser anneal step can be performed after a metal deposition layer is deposited on the wafer surface (p or n type layer). Hence a good activation level can be achieved with lower laser energies (which can be better from the process capability and surface damage after laser annealing) and a good contact is formed (by the intermetal compound layer and/or by a sinter step). FIG. 11 shows the doping concentration achieved by a known sintering compared to a known laser anneal, and an improvement by adding a Ti deposition layer before the laser anneal step as disclosed herein. The doping concentration can rise from, for example, about 5*10¹⁶ cm⁻³ to 1*10¹⁸ cm⁻³ for known laser anneal and further to, for example, 8*10¹⁹ cm⁻³ for a laser anneal and a wafer having a Ti deposition layer as disclosed herein.

After the laser anneal step, final soldering metals can be deposited such as Ti, Ni or Ag with a small anneal step. The same metal may be used as a metal deposition layer and as a first metal electrode layer.

For applying the dopant by deposition, such as evaporation or sputtering, to form the layer of the first or second conductivity type, a single tool can be used for the deposition of the dopant and the deposition of the metal deposition layer.

For manufacturing an insulated gate bipolar transistor as disclosed herein, exemplary steps as disclosed herein are performed.

An (n−) doped wafer 1 having a first and second main side 11, 15 opposite to the first main side 11 is provided. The wafer 1 may be made on a basis of a silicon or a wide bandgap wafer. Such part of wafer having unamended doping concentration in the finalized device forms a drift layer 10. Wafer 1 can, for example, have a constantly low doping concentration. Therein, the substantially constant doping concentration of the wafer (wherein the part of the wafer having unamended doping concentration in the finalized device forms a drift layer 10) means, for example, that the doping concentration is substantially homogeneous throughout the wafer 1 (drift layer 10), however without excluding that fluctuations in the doping concentration within the wafer 1 (drift layer 10) being in the order of a factor of one to five may be possibly present due, for example, to a manufacturing process of the wafer being used.

On the second main side 15, an n dopant is applied and diffused into the wafer 1 for the creation of the buffer layer 13.

Alternatively, the following exemplary steps can be directly performed on an (n−) doped wafer without creating a buffer layer on it (e.g., the step of creating a buffer layer is omitted and a non punch-through device is manufactured). In this case, on the second side 15, the collector layer 2, 2′ as described in the following is created directly neighboured to the (n−) doped drift layer 10.

Afterwards the following steps can be performed for the creation of layers on the first main side 11. For forming a base layer 5, p dopants are applied on the first main side 11 and diffused into the wafer 1.

Then n type dopants for creation of the source regions 6 are implanted on the first main side 11 and annealed.

Afterwards the wafer is for example thinned on the second main side 15 to leave a tail section of the buffer layer, if the device includes a buffer layer, or to reduce the drift layer thickness to an electrically desired thickness.

These steps are only meant as an example for the creation of the layers on the first main side 11 of the wafer and the buffer layer 13. Any other order (e.g., creating part of the layers on the first main side 11 at a later stage than described beforehand) are also covered by the disclosure; for example, the first and second metal electrode layers 4, 8 may be created simultaneously.

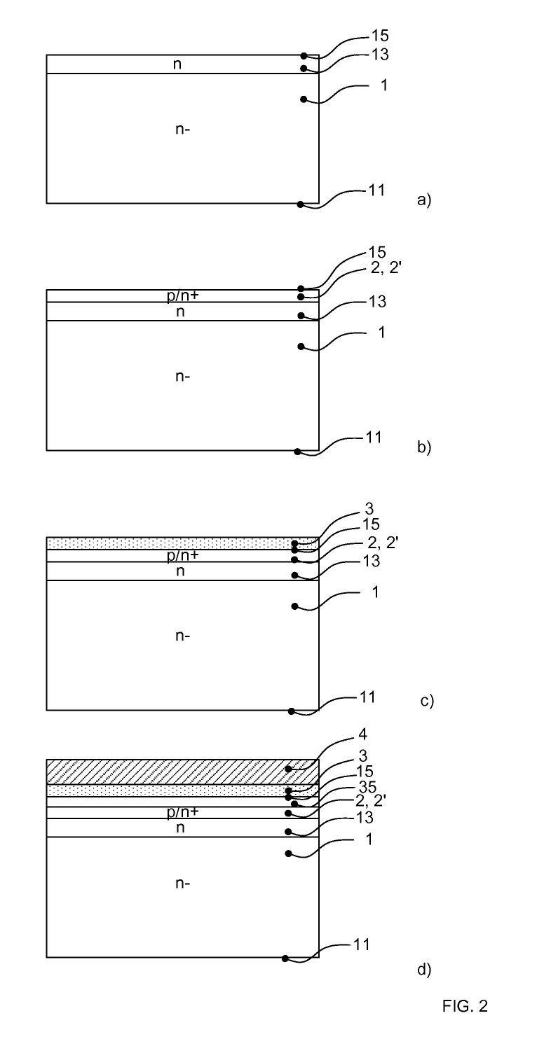

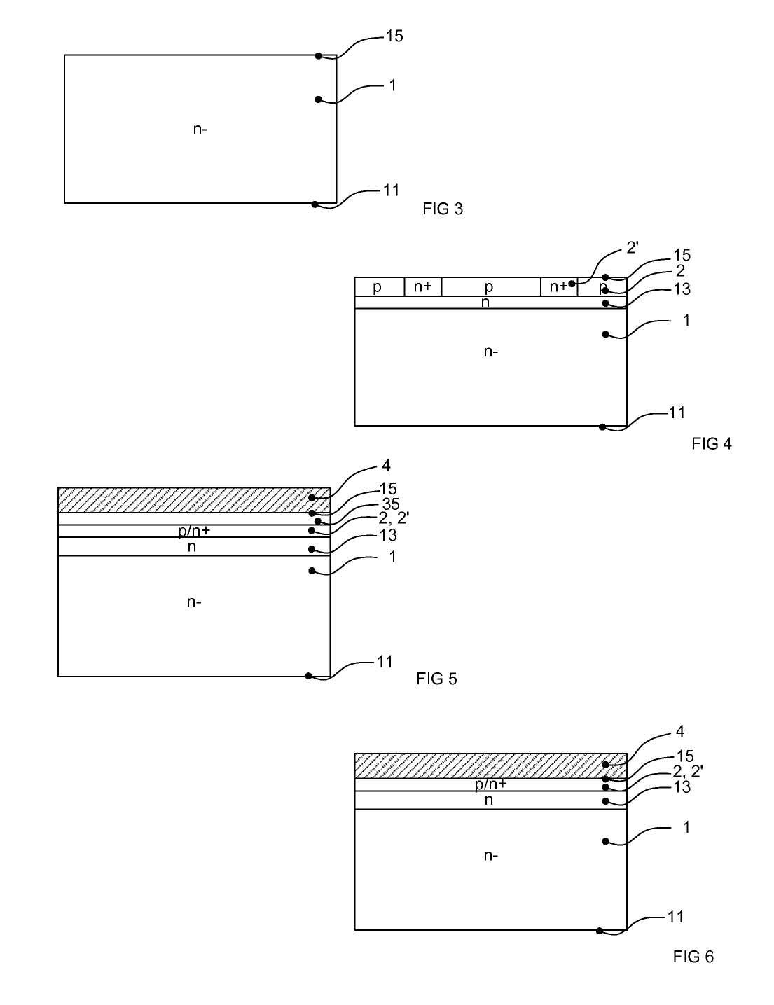

An exemplary method disclosed herein can start by providing a wafer which wafer has a first main side 11 and a second main side 15 opposite to the first main side 11, wherein the wafer has an n doped layer (which later forms the buffer layer) on the second main side 15 (FIG. 2a). Alternatively, an exemplary method may start by providing an (n−) doped wafer which does not have any differently doped layer on the second main side 15 as shown in FIG. 3. In FIGS. 2 to 6, only the second main sided layers have been shown. The layers on the first main side 11 are not part of these figures for clarity reasons.

For the creation of the layers on the second main side 15 the following exemplary steps can be performed:
applying a dopant of a second conductivity type, which is different from the first conductivity type, or of the first conductivity type on the second main side 15, for forming a layer 2 of the second or first conductivity type (FIG. 2b),
afterwards depositing a metal deposition layer 3, wherein the metal is Titanium, on the second main side 15 (FIG. 2c),
annealing the Titanium deposition layer 3 so that an intermetal compound layer 35 is formed at the interface between the metal deposition layer 3 and the wafer 1 and so that the dopant is diffused into the wafer 1,
creating a first metal electrode layer 4 on the second side 15.

The dopant for the creation of the n or p doped layer layer 2,2′ can be applied on the second main side 15 by deposition or implantation of the dopant. Depending on the semiconductor type the dopant is of n or p type. For example, in case of the semiconductor being a diode the dopant may be of n type, in case of the semiconductor being an IGBT, a p type dopant is applied. Also pre-doped amorphous silicon (pre-doped either with n or p type ions) can be applied as a dopant.

In case of the semiconductor being a reverse conducting device, an n type dopant and another dopant of p type can be applied so that n and p layers are created which alternate in a plane parallel to the second main side (FIG. 4).

For depositing, a metal deposition layer of Titanium with its melting point of 1660° C. can be used, which melting point lies above that of silicon. The thickness of the Titanium deposition layer is for example between 5 to 200 nm, in particular for example between 20 to 200 nm, in particular for example between 10 to 100 nm, in particular for example 10 to 50 nm or in particular for example 50 to 100 nm. The annealing of the Titanium deposition layer 3 is for example done by laser annealing.

The Titanium deposition layer 3, which functions as a light absorbing layer, and the dopant are afterwards annealed by laser annealing. This is preferred using an exemplary energy of 1-1.5 J/cm², in particular for example of 1 J/cm². By this laser annealing in case of the wafer being made of silicon, Titanium forms a silicide layer (intermetal compound layer) together with the silicon. The intermetal compound layer 35 being formed at the interface between the Titanium deposition layer 3 and the wafer 1 shall mean that Titanium diffuses from the Titanium deposition layer 3 into the wafer 1 and the silicon into the Titanium layer (e.g., the intermetal compound layer 35 is arranged below the Titanium deposition layer 3 and from the second main side 15 of the wafer to a depth). The thickness of the intermetal compound layer is the depth, up to which the layer 35 extends in the wafer from the wafer surface (second main side 15). It corresponds for example to the thickness of the Titanium deposition layer up to 4 times the thickness of the Titanium deposition layer, for example up to three times the thickness.

The intermetal compound layer is a layer, in which the metal from the metal deposition layer, (e.g., Titanium), diffuses into the wafer (solid-state diffusion) and the metal forms a compound with the wafer material. In case of a silicon wafer silicides are formed. For example, silicon forms with titanium TiSi₂. The term “intermetal” is used in the present patent application as to refer to the silicide layer created by the diffusion of the metal (i.e. Titanium) of the Titanium deposition layer into the silicon wafer. It may also be called Titanium—wafer compound layer or simply Titanium—wafer layer.

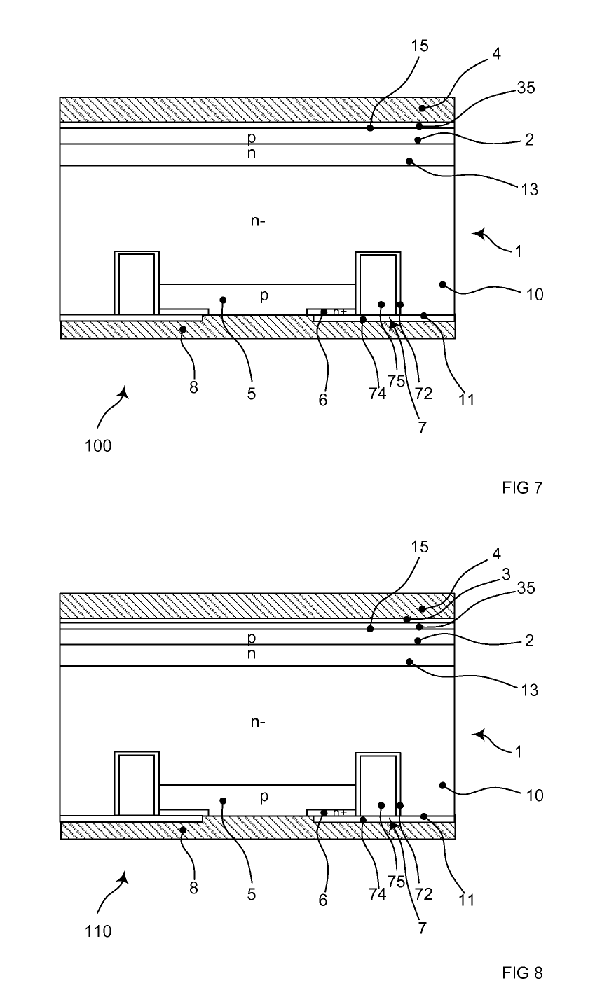

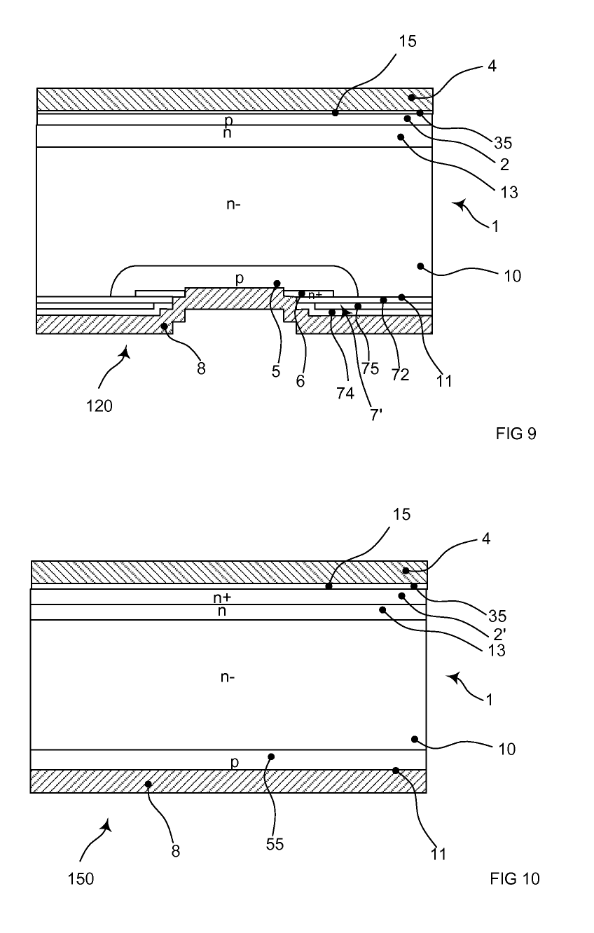

Before creating the first metal electrode layer 4 the intermetal compound layer 35 together with the Titanium deposition layer 3 may be removed (FIG. 6). Alternatively, the intermetal compound layer 35 may be kept, whereas in this case the Titanium deposition layer 3 may either also be kept (FIG. 2d), the IGBT 110 disclosed herein having, for example, these layers (e.g., shown in FIG. 8) or be removed before creating the first metal electrode layer 4 (FIG. 5; IGBT with intermetal layer 35, but without Titanium deposition layer; e.g., FIG. 7 showing IGBT 100, FIG. 9 showing IGBT 120, or FIG. 10 showing a diode 150 as disclosed herein).

For example, in a case in which the same metal is used for the Titanium deposition layer 3 and the metal electrode layer 4 at least on the side of the metal electrode layer facing the Titanium deposition layer 3 the manufacturing step of removing the Titanium deposition layer 3 may be avoided. However, in cases in which different metals are used for the Titanium deposition layer 3 and the first metal electrode layer 4, the deposition layer 3 may also be kept so that the Titanium deposition layer 3, which is electrically conductive, forms part of the first metal electrode layer 4. Thus, the first metal electrode layer 4 forms a sandwiched layer.

After creation of the first metal electrode layer 4, the layer 4 may be sintered for further improving a reliable contact of the first metal electrode layer 4 to the wafer 1.

In FIG. 7, an exemplary power semiconductor device is shown in the form of an insulated gate bipolar transistor 100, which includes a second metal electrode layer 8 in the form of an emitter electrode on the first main side 11 and a first metal electrode layer 4 in the form of a collector electrode on the second main side 15, which second main side 15 is arranged opposite to the first main side 11. An (n−) doped drift layer 10 is arranged between the first main side 11 and the second main side 15. A p doped base layer 5 is arranged between the drift layer 10 and the first main side 11. The base layer 5 contacts the second metal electrode layer 8. At least one n doped source region 6 is arranged on the first main side 11.

The device can include a gate electrode, either in form of a trench gate electrode 7 (FIG. 7, 8) or a planar gate electrode 7′ (FIG. 9).

Such a trench gate electrode 7 can include an electrically conductive layer 75 and a first electrically insulating layer 72, which surrounds and thus separates the electrically conductive layer 75 from the drift layer 10, the base layer 5 and the at least one source region 6. For example, a second insulating layer 74 is arranged between the electrically conductive layer 75 and the second metal electrode layer 8. The trench gate electrode 7 is arranged laterally to the base layer 5 in a plane parallel to the first main side 11.

An exemplary IGBT 120 with planar gate electrode 7′ is shown in FIG. 9. The planar gate electrode 7′ also can include an electrically conductive layer 75, but in this case the gate electrode 7′ is arranged on top of the wafer 1 on the first main side 11. A first electrically insulating layer 72 is arranged between the electrically conductive layer 75 and the wafer 1 such that it separates the electrically conductive layer 75 from the drift layer 10, the base layer 5 and the at least one source region 6. For example, a second insulating layer 74 is arranged between the electrically conductive layer 75 and the second metal electrode layer 8.

The source region 6 is embedded into the base layer 5 such that the source region 6 contacts the second metal electrode layer 8.

On the second main side 15 a p doped layer 2 in form of a collector layer is arranged. An n doped buffer layer 13 having higher doping concentration than the drift layer 10 may be arranged between the drift layer 10 and the collector layer, in general between the drift layer 10 and the second main side 15, wherein the buffer layer adjoins the drift layer 10.

The doping concentration of the source region 6 can be higher than of the base layer 5. Exemplary doping concentrations for the source region 6 are higher than 1*10¹⁸ cm⁻³ and smaller than 1*10²¹ cm⁻³, for example, between 1*10¹⁹ cm⁻³ and 1*10²⁰ cm−3.

The doping concentration of the base layer 5 and the drift layer 10 can be freely chosen due to the application needs and the rules for the doping concentrations given above. For devices above 600 V the doping concentration of the drift layer can, for example, be below 5*10¹⁴ cm⁻³. The base layer 5 can, for example, have a doping concentration below 5*10^{18 cm}⁻³.

The structures as described herein can form an active cell. The IGBT device may include only one active cell as disclosed, but it is also possible that the device comprises at least two or more such active cells (e.g., the active cells can be repetitively arranged in one wafer).

In FIG. 10 an exemplary diode 150 is shown, which includes on the first main side a p doped anode layer 55. On second main side 15, an n doped layer 2′ is included, on which during manufacturing the metal deposition layer 3 has been applied. Depending on the application, the buffer layer 13 present in FIG. 10 between drift layer 10 and first layer 2′ may also be omitted. In FIG. 10 the device can include the intermetal compound layer 35, but as stated before this layer may also have been removed or the Titanium deposition layer 3 may also have been kept.

In another exemplary embodiment, the conductivity types can be switched, (e.g., all layers of the first conductivity type are p type (e.g. the wafer 1) and all layers of the second conductivity type are n type (e.g., layer 2, if layer 2 is of a different conductivity type than wafer 1)).

It should be noted that the term “comprising” does not exclude other elements or steps and that the indefinite article “a” or “an” does not exclude the plural. Also elements described in association with different embodiments may be combined. It should also be noted that reference signs in the claims shall not be construed as limiting the scope of the claims.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE LIST

1 Wafer

10 drift layer

11 first main side

13 buffer layer

15 second main side

100, 110, inventive IGBT

120

150 inventive diode

2, 2′ layer of first or second conductivity type

3 Titanium deposition layer

35 intermetal compound layer

4 first metal electrode layer

5 base layer

55 anode layer

6 source region

7, 7′ gate electrode

72 first insulating layer

74 second insulating layer

75 electrically conductive layer

8 second metal electrode layer

1. A method for manufacturing a power semiconductor device, comprising:
providing a wafer of a first conductivity type, which wafer has a first main side and a second main side opposite to the first main side, part of the wafer having unamended doping concentration forming a drift layer;
applying on the second main side at least one of a dopant of the first conductivity type for forming a layer of the first conductivity type and a dopant of a second conductivity type, which is different from the first conductivity type, for forming a layer of the second conductivity type;
depositing a Titanium deposition layer on the second main side after the applying of the dopant;
laser annealing the Titanium deposition layer at a temperature higher than 1200° C. so that simultaneously an intermetal compound layer is formed at an interface between the Titanium deposition layer and the wafer and the at least one dopant is diffused into the wafer, and so that the Titanium deposition layer will act as a light absorber to achieve an increased temperature in the wafer below the Titanium deposition layer and
creating a first metal electrode layer on the second side.

2. The method according to claim 1, comprising:
depositing the Titanium deposition layer with a thickness between 5 to 200 nm.

3. The method according to claim 1, comprising:
applying the at least one dopant by implanting or depositing the dopant.

4. The method according to claim 1, comprising:
applying the at least one dopant by depositing pre-doped amorphous silicon as dopant.

5. The method according to claim 1, comprising:
sintering the first metal electrode layer.

6. The method according to claim 1, comprising:
removing the intermetal compound layer and the Titanium deposition layer before creating the first metal electrode layer.

7. The method according to claim 1, comprising:
removing the Titanium deposition layer and keeping the intermetal compound layer before creating the first metal electrode layer.

8. The method according to claim 1, comprising:
providing a silicon or wide bandgap wafer as the wafer.

9. The method according to claim 1, comprising:
introducing a buffer layer into the wafer before providing the wafer, which buffer layer is introduced between the drift layer and the second main side, and which buffer layer has higher doping concentration than the drift layer.

10. The method according to claim 1, comprising:
laser annealing the Titanium deposition layer at a temperature higher than 1300° C.

11. The method according to claim 1, comprising:
manufacturing an IGBT as a reverse conducting IGBT, or a diode, as the power semiconductor device.

12. The method according to claim 1, comprising:
depositing the Titanium deposition layer with a thickness between 10 to 50 nm.

13. The method according to claim 2, comprising:
applying the at least one dopant by implanting or depositing the dopant.

14. The method according to claim 2, comprising:
applying the at least one dopant by depositing pre-doped amorphous silicon as dopant.

15. The method according to claim 13, comprising:
sintering the first metal electrode layer.

16. The method according to claim 13, comprising:
removing the intermetal compound layer and the Titanium deposition layer before creating the first metal electrode layer.

17. The method according to claim 13, comprising:
removing the Titanium deposition layer and keeping the intermetal compound layer before creating the first metal electrode layer.

18. The method according to claim 17, comprising:
providing a silicon or wide bandgap wafer as the wafer.

19. The method according to claim 18, comprising:
introducing a buffer layer into the wafer before providing the wafer, which buffer layer is introduced between the drift layer and the second main side, and which buffer layer has higher doping concentration than the drift layer.

20. The method according to claim 19, comprising:
manufacturing an IGBT as a reverse conducting IGBT, or a diode, as the power semiconductor device.
